(19) United States
(12) Patent Application Publication
(10) Pub. No.: US 2002/0137264 A1
(43) Pub. Date: Sep. 26, 2002

(54) Method of fabrication thin wafer IGBT

(76) Inventors: Ming-Jer Kao, Tainan (TW); Chien-Chung Hung, Taipei (TW); Jeng-Hua Wei, Taipei (TW); Jih-Shin Ho, Kaohsiung (TW)

Correspondence Address: Raymond Sun, 12420 Woodhall Way, Tustin, CA, 92782, US

(21) Appl. No.: 09/815,786

(22) Filed: Mar. 23, 2001

(51) Int. Cl. H01L 21/332; H01L 21/8222; H01L 21/331; H01L 27/102; H01L 29/74; H01L 31/11; H01L 29/70; H01L 27/082; H01L 31/111

(52) U.S. Cl. 438/138; 438/140; 257/586; 257/138; 257/153

(57) ABSTRACT

Disclosed is a method for fabricating thin wafer insulated gate bipolar transistors (IGBTs), in which a portion on the back side of the device region is removed to form a hollow region with a depth that results in a device region thickness equivalent to the thickness of a thin wafer while the rest of the wafer remains its standard thickness. In other words, the method according to the present invention is suitable for the currently used wafer transfer stations under thin wafer conditions. The non-punch-through type insulated gate bipolar transistor (NPT-IGBT) fabricated with this method gets rid of an epi-layer and the “lifetime killer” process. The punch-through type insulated gate bipolar transistor (PT-IGBT) fabricated with this method has higher switching efficiency due to reduced injection efficiency of the p⁺-type minority carriers. To sum up, the method of the present invention can tremendously increase the processing yield by solving the problems related to wafer transfer and thus effectively reduce the fabrication cost.

### BACKGROUND OF THE INVENTION

1. Field of the Invention

The present invention generally relates to a method for fabricating thin wafer insulated gate bipolar transistors (to be abbreviated as IGBTs hereinafter), in which a hollow region is formed on the back side of the device region of the insulated gate bipolar transistors, so that the device region achieves equivalent thin wafer thickness.

2. Description of the Prior Art

In recent years, with the rapid growth of semiconductor science and technology, power devices have achieved tremendous improvement in performances such a wider range of operation voltage and/or current and a higher switching efficiency, while remaining other characteristics of the power devices. Among the mentioned power devices, insulated gate bipolar transistors (IGBTs) have been widely applied in high power circuits. Please refer to FIG. 1 for the related techniques for the fabrication of an IGBT by using an epitaxial layer (epi-layer) in one of the prior arts.

FIG. 1 is a cross-sectional view illustrating the fabrication of a punch-through type IGBT (PT-IGBT). Typically, the IGBT 10 comprises a gate 12, an emitter 14, and a collector 16. The IGBT 10 also comprises a p⁺-substrate 20. Upon the p⁺-substrate 20 there is an n⁺-buffer layer 30. Upon the n⁺-buffer layer 30 there is an epi-layer 40. Moreover, there is diffused a p-type deep base 50 upon the epi-layer 40, and finally an n⁺-emitter region 60 is formed. However, the process steps for forming the n⁺-buffer layer 30 and the epi-layer 40 as well the “lifetime killer” process greatly increase the fabrication cost and thus reduce the competitive advantages of the product.

Most of the research institutes have stepped into the research and development of the 5^{th} generation IGBT. The 5^{th} generation IGBT is generally concerned about the related techniques in which a thin wafer (<200 μm in thickness) is used without incorporating an epi-layer. The 5^{th} generation IGBT has advantages in a much lower fabrication cost and a lower switching loss over the conventional IGBTs. Please refer to FIG. 2 for the related techniques for the fabrication of the 5^{th} generation IGBT in another prior art. FIG. 2 is a cross-sectional view illustrating the fabrication of a non-punch-through type IGBT (NPT-IGBT), which is characterized in that a thin wafer as well as a “lifetime killer” free process is used without incorporating an epi-layer so as to reduce the fabrication cost.

As shown in FIG. 2, the IGBT 100 comprises a gate 145, an emitter 135, and a collector 165. The IGBT 10 also comprises an n-type substrate 110. Upon the n-type substrate 110 there is deposited a p-type deep base 120 and an n⁺-emitter region 130. An insulated gate region 140 is formed in the p-type deep base 120 and the n⁺-emitter region 130. Moreover, there is diffused a p⁺-collector region 160 on the back side of the n-type substrate 110. Finally, the contact windows of the gate 145, the emitter 135 and the collector 165 are formed and thus an IGBT is completed as shown in FIG. 2. However, the processing technology for forming the 5^{th} generation IGBT encounters a great challenge in thin wafer process. Due to the thinning of the wafer, the wafer may crack or deform during the following processing steps including wafer transfer between process stations, and thus the yield may be decreased.

### SUMMARY OF THE INVENTION

In order to overcome the problem in the prior arts, the present invention provides an improved method for fabricating thin wafer insulated gate bipolar transistors (IGBTs), so as to reduce the fabrication cost of the IGBTs. According to the method of the present invention, a portion on the back side of the device region is removed to form a hollow region with a depth that results in an equivalent device region thickness less than 200 μm while the rest of the wafer remains its standard thickness. In other words, the method according to the present invention is suitable for the currently used wafer transfer stations under thin wafer conditions.

It is thus the primary object of the present invention to provide a method, in which IGBTs can be fabricated by using the currently used processing stations, so as to reduce the difficulty in device fabrication and increase the fabrication yield by solving the problems related to wafer transfer between processing stations.

In order to achieve the foregoing object, the present invention provides a method for forming a hollow region, including the steps of using a photo-mask alignment step to define a region after the thick wafer process; etching the defined region to form a hollow; implanting ions into the hollow by ion implantation; and forming a collector by annealing.

### BRIEF DESCRIPTION OF THE DRAWINGS

The objects, spirits and advantages of the preferred embodiment of the present invention will be readily understood by the accompanying drawings and detailed descriptions, wherein:

FIG. 1 is a cross-sectional view illustrating the fabrication of a thin wafer punch-through type insulated gate bipolar transistor (PT-IGBT) by using a epi-layer and a buffer layer in one of the prior arts;

FIG. 2 is a cross-sectional view illustrating the fabrication of a thin wafer non-punch-through type insulated gate bipolar transistor (NPT-IGBT) in another prior art;

FIG. 3 is a cross-sectional view illustrating the fabrication of a thin wafer punch-through type insulated gate bipolar transistor (PT-IGBT) in accordance with one embodiment of the present invention;

FIG. 4 is a cross-sectional view illustrating the fabrication of a thin wafer non-punch-through type insulated gate bipolar transistor (NPT-IGBT) in accordance with another embodiment of the present invention; and

FIG. 5 is a flow chart illustrating the fabrication steps of a thin wafer IGBT in accordance with the embodiments of the present invention.

### DETAILED DESCRIPTION OF THE INVENTION

The present invention provides an improved method for fabricating thin wafer insulated gate bipolar transistors, in which standard wafers can be used to fabricate the IGBTs fabricated by using the 5^{th} generation IGBT fabrication method. Presently, the 5^{th} generation IGBT is fabricated by using wafer thinning (down to a thickness less than 200 μm) after the front side process, back-side ion implantation, and annealing. However, due to the thinning of the wafer, the wafer may crack or deform during the following processing steps including wafer transfer between process stations, and thus the yield may be decreased.

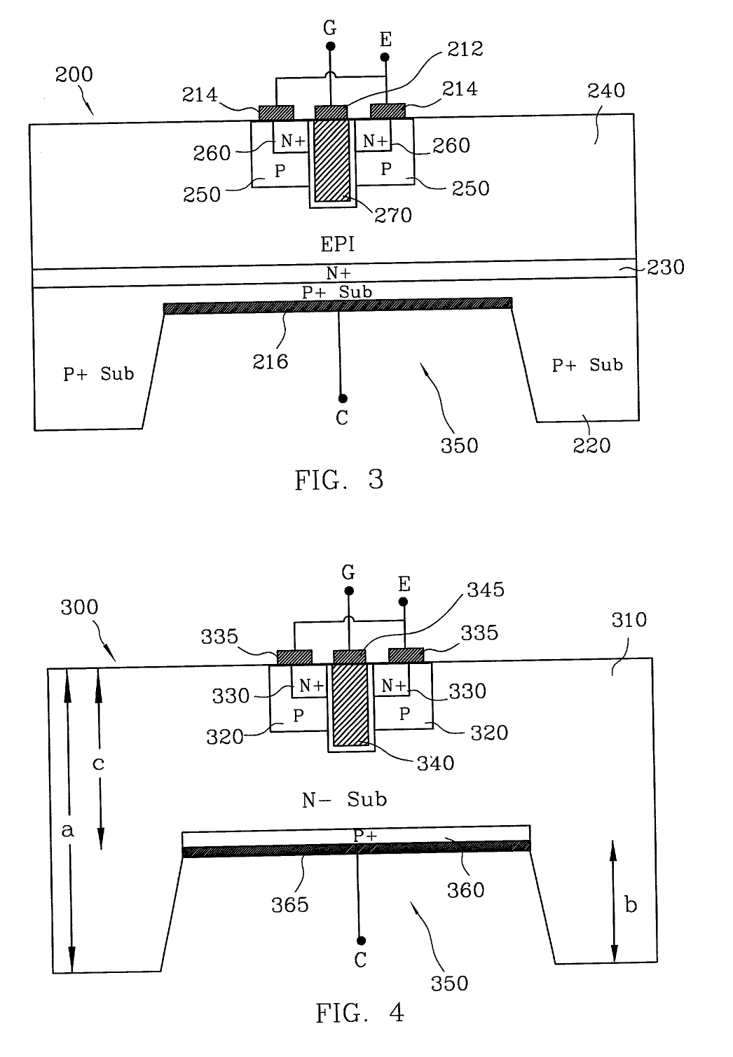

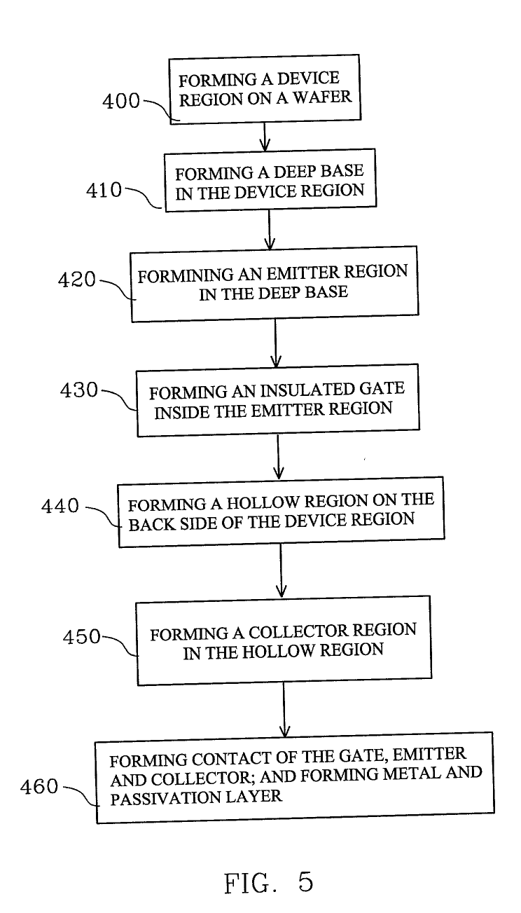

According to the present invention, on the back side of the device region there is formed a hollow region with a depth that results in a device region thickness equivalent to the thickness of a thin wafer (less than 200 μm) while the rest of the wafer remains its standard thickness. This method can be used in the fabrication of both thin wafer punch-through type insulated gate bipolar transistors (PT-IGBTs) and thin wafer non-punch-through type insulated gate bipolar transistors (NPT-IGBTs). Please refer to FIG. 3 and FIG. 4, in which FIG. 3 is a cross-sectional view illustrating the fabrication of a thin wafer punch-through type IGBT (PT-IGBT) in accordance with one embodiment of the present invention, and FIG. 4 is a cross-sectional view illustrating the fabrication of a thin wafer non-punch-through type IGBT (NPT-IGBT) in accordance with another embodiment of the present invention.

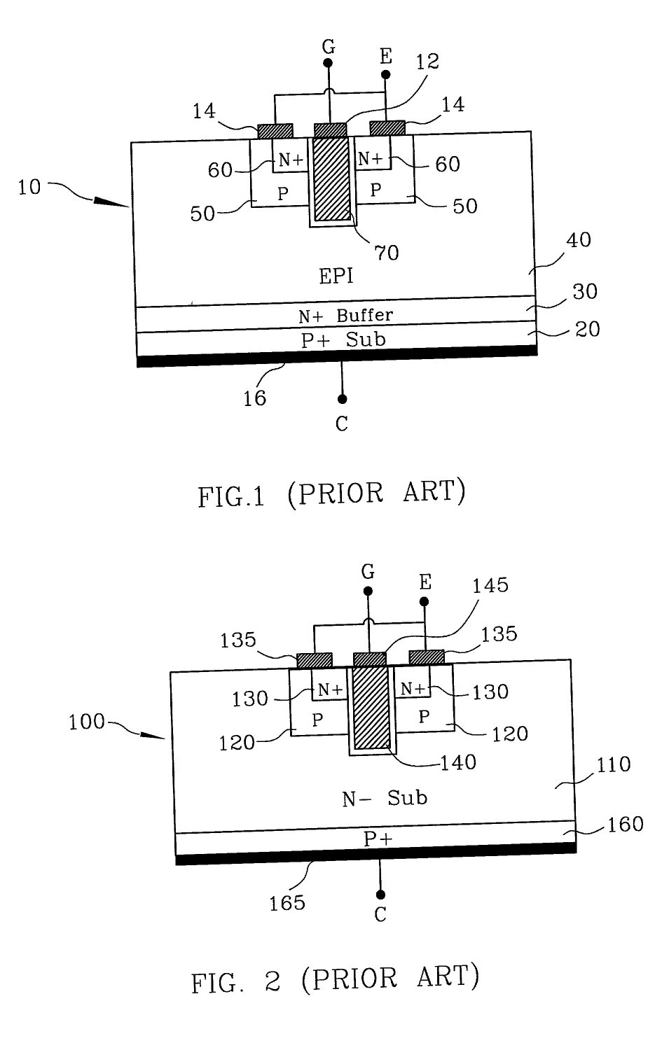

To begin with, compared to the conventional punch-through insulated gate bipolar transistor (PT-IGBT) as shown in FIG. 1, the IGBT 200 as shown in FIG. 3 also comprises a gate 212, an emitter 214, and a collector 216. The IGBT 200 further comprises a p⁺-substrate 220. Upon the p⁺-substrate 220 there is an n⁺-buffer layer 230. Upon the n⁺-buffer layer 230 there is an epi-layer 240. Moreover, there is diffused a p-type deep base 250 upon the epi-layer 240, and finally an n⁺-emitter region 260 is formed. The method of the present invention is characterized in that there is formed a hollow region 350 on the back side of the device region of the insulated gate bipolar transistors 200, and then a collector 216 is formed in the hollow region 350.

On the other hand, compared to the conventional non-punch-through insulated gate bipolar transistor (NPT-IGBT) as shown in FIG. 2, the IGBT 300 as shown in FIG. 4 also comprises a gate 345, an emitter 335, and a collector 365. The IGBT 310 also comprises an n-type substrate 310. Upon the n-type substrate 310 there is deposited a p-type deep base 320 and an n⁺-emitter region 330. The wafer 310 is an n-type drift region with a thickness “a” of about 250 μm. An insulated gate region 340 is formed and isolated in the p-type deep base 320 and the n⁺-emitter region 330.

Moreover, the method of the present invention is characterized in that a portion on the back side of the device region of the wafer 310 is removed to form a hollow region 350. The hollow region 350 is formed by using micro-electromechanical system (MEMS) technology, which comprised the steps of using a photo-mask alignment step to define a region after the thick wafer process, etching the defined region to form a hollow, implanting ions into the hollow by ion implantation, and forming an collector 360 by annealing. The depth “b” of the hollow region is 100 μm, resulting in a device region thickness “c” equivalent to the thickness of a thin wafer (about 150 μm), so as to form a thin wafer IGBT device. Then, the contact windows of the gate 345, the emitter 335 and the collector 365 are formed and filled with metal. Finally, a passivation layer (not shown) is deposited and thus an IGBT is completed as shown in FIG. 4.

To further describe the fabrication steps of the IGBTs in accordance with the embodiments of the present invention, please refer to FIG. 5, which is a flow chart illustrating the fabrication steps of a thin wafer IGBT. Note that the method disclosed in FIG. 5 can be used in the fabrication of both thin wafer punch-through type insulated gate bipolar transistors (PT-IGBTs) and thin wafer non-punch-through type insulated gate bipolar transistors (NPT-IGBTs). The method as shown in FIG. 5 comprises the steps of: forming a device region on a wafer 400 by using a photo-mask alignment step to define the device region; forming a deep base in the device region 410, wherein the deep base is p-type; forming an emitter region in the deep base 420 by implanting p⁺-type ions; forming an insulated gate inside the emitter region 430 by forming a trench by etching and then filling the trench with oxide and poly-silicon; forming a hollow region on the back side of the device region 440 (as the region labeled 350 shown in FIG. 3) by using a photo-mask alignment step to define a hollow region and then etching the region; forming a collector region in the hollow region 450 by implanting p⁺-type ions and then annealing; and forming contact windows of the gate, the emitter, and the collector, filling the windows with metal, and depositing a passivation layer 460.

The major advantage of the present invention is that this method is suitable for the currently used wafer transfer stations under thin wafer conditions, thus it can tremendously increase the processing yield by solving the problems related to wafer transfer and effectively reduce the fabrication cost. Compared to the IGBT as shown in FIG. 1, the IGBT shown in FIG. 2 can get rid of an epi-layer and the “lifetime killer” process, so as to effectively reduce the fabrication cost and tremendously increase the processing yield.

As discussed so far, in accordance with the present invention, there is provided a method for fabricating thin wafer insulated gate bipolar transistors (IGBTs) that can tremendously increase the processing yield by solving the problems related to wafer transfer and thus effectively reduce the fabrication cost. Consequently, the present invention has been examined to be progressive and has great potential in commercial applications.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is

1. A method for fabricating thin wafer insulated gate bipolar transistors (IGBTs), wherein on the back side of the device region there is formed a hollow region with a depth that results in a device region thickness equivalent to the thickness of a thin wafer while the rest of the wafer remains its standard thickness so as to complete IGBT fabrication by using conventional processing stations.

2. The method for fabricating thin wafer insulated gate bipolar transistors as recited in claim 1, wherein said method for forming said hollow region comprises the steps of:
(a) defining a region;
(b) etching said defined region to form a hollow;
(c) implanting ions into said hollow by ion implantation; and
(d) forming a collector of said insulated gate bipolar transistor by annealing.

3. The method for fabricating thin wafer insulated gate bipolar transistors as recited in claim 1, wherein the depth of said hollow region is 100 μm.

4. The method for fabricating thin wafer insulated gate bipolar transistors as recited in claim 1, wherein the equivalent thickness of said device region is 150 μm.

5. The method for fabricating thin wafer insulated gate bipolar transistors as recited in claim 1, wherein the thickness of the rest of said wafer is 250 μm.

6. The method for fabricating thin wafer insulated gate bipolar transistors as recited in claim 1 can be used in the fabrication of a thin wafer punch-through type insulated gate bipolar transistor (PT-IGBT).

7. The method for fabricating thin wafer insulated gate bipolar transistors as recited in claim 1 can be used in the fabrication of a thin wafer non-punch-through type insulated gate bipolar transistor (NPT-IGBT).

8. The method for fabricating thin wafer insulated gate bipolar transistors as recited in claim 2, wherein said step (a) is performed by using a photo-mask alignment step to define said region.

9. The method for fabricating thin wafer insulated gate bipolar transistors as recited in claim 2, wherein said step (c) is performed by implanting p⁺-ions.

10. A method for fabricating thin wafer insulated gate bipolar transistors (IGBTs), comprising the steps of:
(a) forming a device region on a wafer;
(b) forming a deep base in said device region;
(c) forming an emitter region in said deep base;
(d) forming an insulated gate inside said emitter region;
(e) forming a hollow region on the back side of said device region;
(f) forming a collector region in said hollow region; and
(g) forming contact windows of the gate, the emitter, and the collector, filling said windows with metal, and depositing a passivation layer.

11. The method for fabricating thin wafer insulated gate bipolar transistors as recited in claim 10, wherein said step (a) is performed by using a photo-mask alignment step to define said region.

12. The method for fabricating thin wafer insulated gate bipolar transistors as recited in claim 10, wherein said deep base of said step (b) is p-type.

13. The method for fabricating thin wafer insulated gate bipolar transistors as recited in claim 10, wherein said step (c) is performed by implanting p⁺-type ions.

14. The method for fabricating thin wafer insulated gate bipolar transistors as recited in claim 10, wherein said step (d) is performed by forming a trench by etching and then filling said trench with oxide and poly-silicon.

15. The method for fabricating thin wafer insulated gate bipolar transistors as recited in claim 10, wherein said step (e) is performed by using a photo-mask alignment step to define a hollow region and then etching said region.

16. The method for fabricating thin wafer insulated gate bipolar transistors as recited in claim 10, wherein said step (f) is performed by implanting p⁺-type ions and then annealing.

17. The method for fabricating thin wafer insulated gate bipolar transistors as recited in claim 10 can be used in the fabrication of a thin wafer punch-through type insulated gate bipolar transistor (PT-IGBT).

18. The method for fabricating thin wafer insulated gate bipolar transistors as recited in claim 10 can be used in the fabrication of a thin wafer non-punch-through type insulated gate bipolar transistor (NPT-IGBT).

19. A thin wafer insulated gate bipolar transistor (IGBT), wherein in a device region of a wafer there are an emitter, a collector and a gate, and on the back side of a device region there is a hollow region; wherein said emitter and said gate are the top surface of said device region while said collector is on the back side of said device region.

20. The thin wafer insulated gate bipolar transistor as recited in claim 19, wherein the depth of said hollow region is 100 μm.

21. The thin wafer insulated gate bipolar transistor as recited in claim 19, wherein the equivalent thickness of said device region is 150 μm.

22. The thin wafer insulated gate bipolar transistor as recited in claim 19, wherein the thickness of the rest of said wafer is 250 μm.
